(19) United States
(12) Patent Application Publication
(10) Pub. No.: US 2025/0310074 A1
(43) Pub. Date: Oct. 2, 2025

(54) Environmental-based parameters optimization of clock

(71) Applicant: Mellanox Technologies, Ltd., Yokneam (IL)

(72) Inventors: Nir Laufer, Zoran (IL); Dotan David Levi, Kiryat Motzkin (IL); Bar Shapira, Tel Aviv (IL); Natan Manevich, Nesher (IL); Dror Porat, Haifa (IL); Gil Shabat, Hod Hasharon (IL)

(21) Appl. No.: 18/624,169

(22) Filed: Apr. 2, 2024

(51) Int. Cl. H04L 7/00; G06F 1/08; G06F 1/12

(52) U.S. Cl. CPC H04L 7/0016; G06F 1/08; G06F 1/12

(57) ABSTRACT

In one embodiment, a device includes clock circuitry including an oscillator to generate a local clock signal having a clock frequency, and a hardware clock to maintain a local clock responsively to the clock signal, at least one sensor to measure at least one value of at least one environmental parameter, processing circuitry to find at least one value of at least one filter parameter based on the at least one value of the at least one environmental parameter, and a filter to receive an error signal between a remote clock and the local clock, and filter the error signal and generate an adjustment to cause the clock circuitry to adjust the local clock signal or the local clock based on the at least one value of the at least one filter parameter.

### FIELD OF THE INVENTION

The present invention relates to computer systems, and in particular, but not exclusively to, clock synchronization.

### BACKGROUND

Clock synchronization among network devices is used in many network applications. One application of using a synchronized clock value is for measuring one-way latency from one device to another device. If the clocks are not synchronized the resulting one-way latency measurement will be inaccurate.

Synchronization is typically achieved by syntonization, in which the clock frequency of two devices is aligned, and aligning the phase between the two devices.

For Ethernet, there are two complementary methods to achieve synchronization. One is Synchronous Ethernet (SyncE), which is a physical-layer protocol which achieves syntonization based on the receive/transmit symbol rate. SyncE is an International Telecommunication Union Telecommunication (ITU-T) Standardization Sector standard for computer networking that facilitates the transference of clock signals over the Ethernet physical layer. In particular, SyncE enables clock syntonization inside a network with respect to a master clock.

The other is Precision Time Protocol (PTP), which is a packet-based protocol that may be used with SyncE to align offset (e.g., in Coordinated Universal Time (UTC) format) and phase between two clocks. PTP is used to accurately synchronize clocks throughout a computer network, and is considered to be the de facto standard for this purpose. PTP is an example of a two-way time synchronization protocol. A two-way time synchronization protocol uses time synchronization packets which are exchanged in both directions between a clock leader and a clock follower.

A remote clock frequency from a remote clock may be recovered (e.g., using SyncE) or remote time (e.g., using PTP) and compared to the local clock providing an error signal. PTP and Sync-E implementations use feedback systems (e.g., with a loop filter or servo filter) to steer the local clock frequency and time iteratively towards a recovered remote master time and frequency, respectively. The filter filters input noise from the error signal while correcting local oscillator frequency variations. The filter may also determine how fast the error should be corrected. In some cases, the filter not only looks at the current error but also the integral of the error (which provides the cumulative error). The performance of the filter is governed by filter parameters which are set by the device designer and may determine how noise is filtered and how quickly the clock error is corrected.

### SUMMARY

There is provided in accordance with an embodiment of the present disclosure, a device, including clock circuitry including an oscillator to generate a local clock signal having a clock frequency, and a hardware clock to maintain a local clock responsively to the local clock signal, at least one sensor to measure at least one value of at least one environmental parameter, processing circuitry to find at least one value of at least one filter parameter based on the at least one value of the at least one environmental parameter, and a filter to receive an error signal between a remote clock and the local clock, and filter the error signal and generate an adjustment to cause the clock circuitry to adjust the local clock signal or the local clock based on the at least one value of the at least one filter parameter.

Further in accordance with an embodiment of the present disclosure, the device includes clock synchronization circuitry to find the error signal between the remote clock and the local clock.

Still further in accordance with an embodiment of the present disclosure, the device includes a temperature sensor to measure temperature of the oscillator, the processing circuitry being to find the at least one value of the at least one filter parameter based on the temperature.

Additionally in accordance with an embodiment of the present disclosure the processing circuitry is to find the at least one value of the at least one filter parameter based on a change in the temperature.

Moreover, in accordance with an embodiment of the present disclosure the processing circuitry is to find the at least one value of the at least one filter parameter based on a rate of change of the temperature.

Further in accordance with an embodiment of the present disclosure the processing circuitry is to find the at least one value of at least one filter parameter based on the temperature and at least one property of the oscillator.

Still further in accordance with an embodiment of the present disclosure the at least one property of the oscillator includes frequency stability as a function of the temperature.

Additionally in accordance with an embodiment of the present disclosure, the device includes a vibration sensor to measure vibration of the oscillator, the processing circuitry being to find the at least one value of the at least one filter parameter based on the vibration.

Moreover, in accordance with an embodiment of the present disclosure the processing circuitry is to find the at least one value of the at least one filter parameter based on the vibration and at least one property of the oscillator.

Further in accordance with an embodiment of the present disclosure the at least one property of the oscillator includes frequency stability as a function of the vibration.

Still further in accordance with an embodiment of the present disclosure the processing circuitry is to intermittently sample the at least one environmental parameter over time yielding multiple sampled values of the at least one environmental parameter, and find updated values of the at least one filter parameter based on the multiple sampled values.

Additionally in accordance with an embodiment of the present disclosure the processing circuitry is to find a cutoff frequency and an update rate of the filter based on the at least one value of the at least one environmental parameter, and compute the at least one value of the at least one filter parameter based on the cutoff frequency and the update rate of the filter.

Moreover, in accordance with an embodiment of the present disclosure the processing circuitry is to perform a table lookup using the at least one value of the at least one environmental parameter to find the cutoff frequency and the update rate.

Further in accordance with an embodiment of the present disclosure the processing circuitry is to predict the cutoff frequency and the update rate from the at least one value of the at least one environmental parameter using a machine learning model while minimizing clock error.

Still further in accordance with an embodiment of the present disclosure the processing circuitry is to predict the cutoff frequency and the update rate from the at least one value of the at least one environmental parameter using reinforcement learning while minimizing clock error.

Additionally in accordance with an embodiment of the present disclosure the processing circuitry is to predict the cutoff frequency and the update rate from the at least one value of the at least one environmental parameter using a Bayesian optimization framework while minimizing clock error.

Moreover, in accordance with an embodiment of the present disclosure the processing circuitry is to perform a table lookup using the at least one value of the at least one environmental parameter to find the at least one value of the at least one filter parameter.

Further in accordance with an embodiment of the present disclosure the processing circuitry is to predict the at least one value of the at least one filter parameter from the at least one value of the at least one environmental parameter using a machine learning model while minimizing clock error.

Still further in accordance with an embodiment of the present disclosure the processing circuitry is to predict the at least one value of the at least one filter parameter from the at least one value of the at least one environmental parameter using reinforcement learning while minimizing clock error.

Additionally in accordance with an embodiment of the present disclosure the processing circuitry is to predict the at least one value of the at least one filter parameter from the at least one value of the at least one environmental parameter using a Bayesian optimization framework while minimizing clock error.

Moreover in accordance with an embodiment of the present disclosure the filter is a PI servo filter and the at least one filter parameter includes PI constants defining a bandwidth of the filter.

There is also provided in accordance with another embodiment of the present disclosure, a method, including generating a local clock signal having a clock frequency, maintaining a local clock responsively to the local clock signal, measuring at least one value of at least one environmental parameter, finding at least one value of at least one filter parameter based on the at least one value of the at least one environmental parameter, receiving an error signal between a remote clock and the local clock, and filtering the error signal and generate an adjustment to cause adjustment of the local clock signal or the local clock based on the at least one value of the at least one filter parameter.

### BRIEF DESCRIPTION OF THE DRAWINGS

The present invention will be understood from the following detailed description, taken in conjunction with the drawings in which:

FIG. 1 is a block diagram view of a clock synchronization system constructed and operative in accordance with an embodiment of the present invention; and

FIG. 2 is a flowchart including steps in a method of operation of the system of FIG. 1.

### DESCRIPTION OF EXAMPLE EMBODIMENTS

### Overview

The local oscillator frequency is sensitive to environmental conditions such as temperature variations and vibration. When the temperature around the oscillator is stable, the oscillator frequency stability is high and the filter should be configured to provide narrow band filtering, allowing better filtering of the input noise. However, when the temperature around the oscillator is unstable, the frequency stability of the oscillator is degraded and the filter should be configured to wide band filtering, allowing the clock synchronization control loop to quickly follow the oscillator frequency changes. Additionally, if the error signal is less noisy, the filter may adjust the clock faster. However, if the error signal is noisier, then it may be desirable to adjust to the remote clock more slowly and rely more on local clock. However, relying on local clock has a trade off as the local clock is generally sensitive to temperature and vibration, for example. For example, the oscillator frequency stability is generally a function of temperature and vibration. Therefore, the filter is unlikely to be set correctly for all the above scenarios and may provide incorrect clock adjustments in many cases.

Therefore, embodiments of the present invention address at least some of the above drawbacks by providing a clock synchronization system in which the value(s) of the filter parameter(s) may be dynamically changed during operation of the system and adjusted based on one or more environmental parameters such as temperature and vibrations. In some embodiments, the value(s) of the filter parameter(s) may be set according to the environmental parameter(s) to minimize the error signal between the remote clock and local clock. In some embodiments, the filter may be a PI servo/filter with parameters P and I defining the filter bandwidth.

One or more temperature sensors and/or vibration sensors may be placed near the oscillator. The sensor(s) may be intermittently sampled to provide metrics such as: temperature, temperature changes, rate of change of temperature, measures of vibration, and changes in vibration, and rate of change of vibration.

The metrics of the environmental parameter(s) may be used along with oscillator properties (e.g., given by the technical specification of the oscillator listing the expected performance of the oscillator based on environmental factors such as temperature and vibration) to adjust the filter characteristics, e.g., cutoff frequency and sampling/update rate of the filter. For example, the system may compute the desired cutoff frequency and update-rate of the filter from the metrics of the environmental parameters (e.g., sampled temperature), and oscillator properties. The value(s) of the filter parameter(s) may then be computed from the computed cutoff frequency and update-rate or directly from the metrics of the environmental parameter(s).

In some embodiments, the value(s) of the filter parameter(s) and/or the cutoff frequency and update-rate may be computed using heuristics (e.g., using a prepopulated table listing rates of change of temperature and corresponding values of the filter parameter(s)). The table may be populated based on prior experimentation by applying different values of the filter parameter(s) for different temperatures and temperature changes and aim to minimize the error signal. In some embodiments, the table may be populated based on artificial intelligence (AI) methods such as Bayesian Optimization (BO), described in disclosed embodiments.

In some embodiments, the values of the filter parameter(s) and/or cutoff frequency and update-rate may be found using reinforcement learning in which exploration may be performed to find the value(s) of the filter parameter(s) that minimize the error signal for given environmental parameter metrics. Once the system is in steady state (e.g., with steady values of the environmental parameters), exploration may be minimized or ceased to allow exploitation with the best value(s) of the filter parameter(s) found during exploration until another change in the environmental parameter(s) is observed.

### System Description

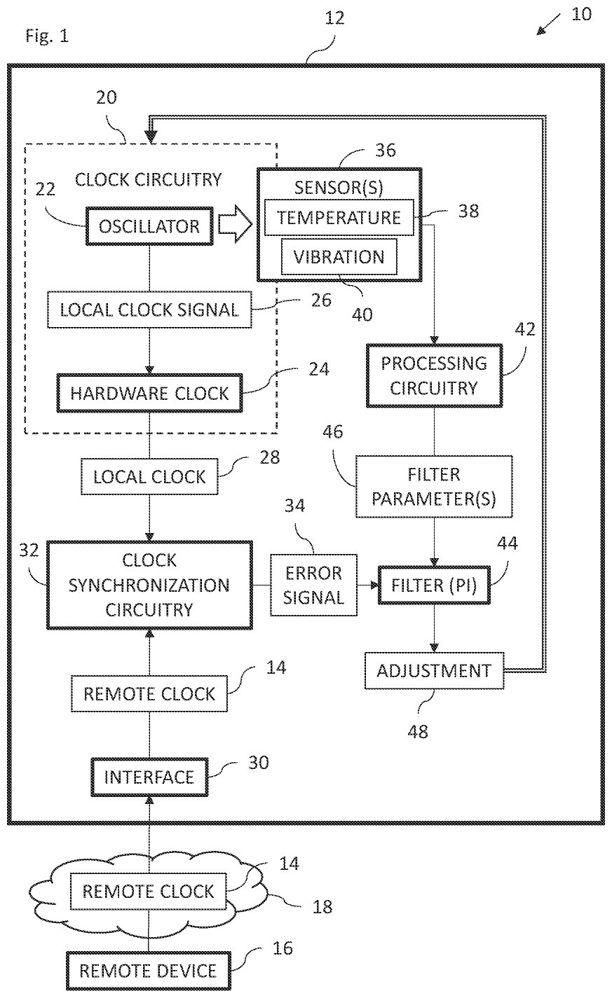

Reference is now made to FIG. 1, which is a block diagram view of a clock synchronization system 10 constructed and operative in accordance with an embodiment of the present invention. The clock synchronization system 10 includes a device 12 (e.g., a network device such as a network interface controller or a switch) which is configured to synchronize its clock to a remote clock 14 provided by a remote device 16, e.g., over a network 18, or connected to the device 12 by any suitable connection, such as a data communication interface.

The device 12 includes clock circuitry 20, which includes an oscillator 22 and a hardware clock 24. The oscillator 22 is configured to generate a local clock signal 26 having a clock frequency. In some embodiments, the oscillator 22 may be a digitally controller oscillator (DCO) which is configured to generate a local clock having a local clock frequency. In some embodiments, the DCO may be a “high end” digitally controlled oscillator, such as Temperature Compensated Crystal Oscillator (TCXO) or an Oven Controlled Crystal Oscillator (OCXO). The hardware clock 24 is configured to maintain a local clock 28 (including a clock time advancing with a clock frequency) responsively to the local clock signal 26. The hardware clock 24 may be configured to maintain a time-of-day value advancing at a frequency proportional to a frequency of the local clock signal 26 output by the oscillator 22.

The device 12 also includes an interface 30 (e.g., a network interface) and clock synchronization circuitry 32. The interface 30 is configured to receive the remote clock 14 from the remote device 16. The remote clock 14 may be conveyed according to any suitable time synchronization protocol to synchronize clock frequency and/or clock time. The remote clock 14 may be conveyed using clock synchronization messages sent by the remote device 16 or exchanged between the device 12 and the remote device 16. The remote clock 14 may be conveyed via a data transfer rate between the remote device 16 and the device 12. The clock synchronization circuitry 32 is configured to find an error signal 34 representing the difference in time or frequency between the remote clock 14 and local clock 28).

The device 12 may also include one or more sensors 36 generally disposed in, or adjacent to, the oscillator 22. The sensor(s) 36 may be disposed as close to the oscillator 22 as possible without interfering with the operation of the oscillator 22. In some cases, the sensor(s) 36 may be disposed at some distance from the oscillator 22 as long as the sensor(s) 36 still measures the environmental parameter(s) within the given accuracy needed for the environmental parameter metrics. The sensor(s) 36 may include any suitable sensor(s) configured to measure values of one or more environmental parameters such as temperature and vibration. In some embodiments, the sensor(s) 36 may include one or more temperature sensors 38 to measure temperature of the oscillator 22 and/or one or more vibration sensors 40 to measure vibration of the oscillator 22. The vibration sensor(s) 40 may include one or more accelerometers and/or measure vibration by monitoring the status of one or more fans running on the device 12.

The device 12 also includes processing circuitry 42 and a filter 44. The processing circuitry 42 is configured to find value(s) of one or more filter parameter(s) 46 based on the value(s) of the environmental parameter(s) sensed by the sensor(s) 36. In some embodiments, the processing circuitry 42 is configured to find value(s) of the filter parameter(s) 46 based on the value(s) of the environmental parameter(s) sensed by the sensor(s) 36 and one or more properties of the oscillator 22 (e.g., a response, such as frequency stability, of the oscillator 22 to (changes) in the value(s) of the environmental parameter(s)).

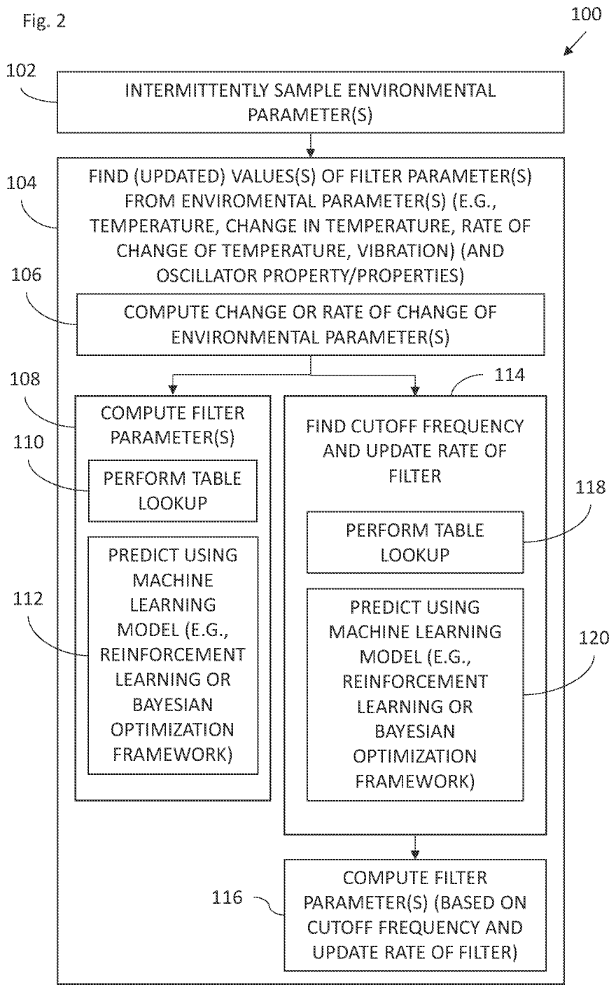

In some embodiments, the processing circuitry 42 is configured to find the value(s) of the filter parameter(s) 46 based on one or more of the following: the temperature value(s) measured by the temperature sensor(s) 38; one or more changes in the value(s) of temperature measured by the temperature sensor(s) 38; one or more rate(s) of change in the value(s) of temperature measured by the temperature sensor(s) 38; and one or more properties of the oscillator 22 (e.g., frequency stability of the oscillator 22 as a function of the temperature or temperature change or rate of change of temperature). The property or properties of the oscillator 22 may be used to generate a lookup table of temperature metrics (e.g., temperature, or change in temperature, or rate of change of temperature with corresponding filter parameter(s) 46) based on the property or properties of the oscillator 22 provided by the manufacturer of the oscillator 22 for example, and/or based on other heuristics described in more detail with reference to FIG. 2.

In some embodiments, the processing circuitry 42 is configured to find the value(s) of the filter parameter(s) 46 based on one or more of the following: value(s) measured by the vibration sensor(s) 40; one or more changes in the value(s) measured by the vibration sensor(s) 40; one or more rate(s) of change in the value(s) measured by the vibration sensor(s) 40; and one or more properties of the oscillator 22 (e.g., frequency stability of the oscillator 22 as a function of the vibration or vibration change or rate of change of vibration). The property or properties of the oscillator 22 may be used to generate a lookup table of vibration metrics (e.g., vibration, or change in vibration, or rate of change of vibration with corresponding filter parameter(s) 46) based on the property or properties of the oscillator 22 provided by the manufacturer of the oscillator 22 for example, and/or based on other heuristics described in more detail with reference to FIG. 2.

In some embodiments, the processing circuitry 42 may find the value(s) of the filter parameter(s) 46 based on a combination of two or more environmental parameters (e.g., temperature and vibration).

The filter 44 is configured to receive the filter parameter(s) 46 found by the processing circuitry 42. The filter 44 is also configured to receive the error signal 34 (between the remote clock 14 and the local clock 28) and filter the error signal 34 and generate an adjustment 48 (e.g., an analogue or a digital signal or one or more commands) to cause the clock circuitry 20 to adjust the local clock signal 26 or the local clock 28 based on the value(s) of the filter parameter(s) 46. Causing the clock circuitry 20 to adjust the local clock signal 26 or the hardware clock 24 may include: the oscillator 22 (e.g., a DCO) changing the frequency of the local clock signal 26 or a digital synthesizer changing the output of the oscillator 22; changing the time value (e.g., counter value) of the hardware clock 24 or conversion parameters used by the hardware clock 24 to convert a counter value maintained by the hardware clock 24 to a time of day value. In some embodiments, the filter 44 is a PI servo filter and the filter parameters 46 includes PI constants defining a bandwidth of the filter 44.

In practice, some or all of the functions of the clock synchronization circuitry 32 and/or the processing circuitry 42 may be combined in a single physical component or, alternatively, implemented using multiple physical components. These physical components may comprise hard-wired or programmable devices, or a combination of the two. In some embodiments, at least some of the functions of the clock synchronization circuitry 32 and/or processing circuitry 42 may be carried out by a programmable processor under the control of suitable software. This software may be downloaded to a device in electronic form, over a network, for example. Alternatively, or additionally, the software may be stored in tangible, non-transitory computer-readable storage media, such as optical, magnetic, or electronic memory.

Reference is now made to FIG. 2, which is a flowchart 100 including steps in a method of operation of the system 10 of FIG. 1. Reference is also made to FIG. 1. The processing circuitry 42 is configured to intermittently sample the environmental parameter(s) by sampling the sensor(s) 36 over time yielding multiple sampled values of the environmental parameter(s) (block 102). The processing circuitry 42 is configured to find updated values of the filter parameter(s) 46 based on the multiple sampled values and optionally based on one or more properties of the oscillator 22 (block 104).

The step of block 104 may include the processing circuitry 42 being configured to compute the change and/or rate of change of the environmental parameter(s) based on the sampled values (block 106).

In some embodiments, the step of block 104 may also include computing the filter parameter(s) 46 based on the sampled values and/or the computed change and/or rate of change of the environment parameters (block 108).

In some embodiments, the step of block 108 includes the processing circuitry 42 being configured to perform a table lookup using the value(s) of the environmental parameter(s) (e.g., sampled values and/or the computed change and/or rate of change of the environment parameters) to find the value(s) of the filter parameter(s) 46 (block 110). The table may be populated based on the given properties of the oscillator 22 as given by the oscillator 22 manufacturer and/or by prior experimentation by applying different values of the filter parameter(s) 46 for different temperatures and/or vibrations and temperature and/or vibration changes and aim to minimize the error signal 34. In some embodiments, the table may be populated based on artificial intelligence (AI) methods such as Bayesian Optimization (BO), described in more detail below.

In some embodiments, the step of block 108 includes the processing circuitry 42 being configured to predict the value(s) of the filter parameter(s) 46 from the value(s) of the environmental parameter(s) (e.g., sampled values and/or the computed change and/or rate of change of the environment parameters) using a machine learning model (block 112) while minimizing clock error. In some embodiments, the processing circuitry 42 is configured to predict the value(s) of the filter parameter(s) 46 from the value(s) of the environmental parameter(s) using reinforcement learning while minimizing clock error, as described in more detail below. In some embodiments, the processing circuitry 42 is configured to predict the value(s) of the filter parameter 46 from the value(s) of the environmental parameter(s) using a Bayesian optimization framework while minimizing clock error, described in more detail below.

In other embodiments, the step of block 104 may also include the processing circuitry 42 being configured to compute a cutoff frequency and an update (or sampling) rate of the filter 44 based on the sampled values and/or the computed change and/or rate of change of the environment parameters (block 114), and then compute the value(s) of the filter parameter(s) 46 based on the computed cutoff frequency and the update rate of the filter 44 (block 116).

In some embodiments, the step of block 114 includes the processing circuitry 42 being configured to perform a table lookup using the value(s) of the environmental parameter(s) (e.g., sampled values and/or the computed change and/or rate of change of the environment parameters) to find the cutoff frequency and the update (or sampling) rate (block 118). The table may be populated based on the given properties of the oscillator 22 as given by the oscillator 22 manufacturer and/or by prior experimentation by applying different values of the cutoff frequency and the update (or sampling) rate for different temperatures and/or vibrations and temperature and/or vibration changes and aim to minimize the error signal 34. In some embodiments, the table may be populated based on artificial intelligence (AI) methods such as Bayesian Optimization (BO), described in more detail below.

In some embodiments, the step of block 114 includes the processing circuitry 42 being configured to predict the cutoff frequency and the update (or sampling) rate from the value(s) of the environmental parameter(s) (e.g., sampled values and/or the computed change and/or rate of change of the environment parameters) using a machine learning model (block 120) while minimizing clock error. In some embodiments, the processing circuitry 42 is configured to predict the cutoff frequency and the update (or sampling) rate from the value(s) of the environmental parameter(s) using reinforcement learning while minimizing clock error, as described in more detail below. In some embodiments, the processing circuitry 42 is configured to predict the cutoff frequency and the update (or sampling) rate from the value(s) of the environmental parameter(s) using a Bayesian optimization framework while minimizing clock error, described in more detail below.

The goal of the optimization process is to find the filter parameter(s) (or the cutoff frequency and the update (or sampling) rate) that minimize the clock error for a given value or values of the environmental parameter(s). Formally, suppose ϵ(t|kₚ, kᵢ, T) is the error at time t, given filter parameters kᵢ and kₚ and environmental parameter metric T, then the goal is to tune the filter parameter(s) to minimize the minimal mean squared error over a given time interval of length τ, e.g., given by the following cost function:

$${k}_{i} , {k}_{p} = argmin \frac{1}{τ} {\int }_{0}^{τ} {\vert ϵ ( t \vert {k}_{p}^{′} , {k}_{i}^{′} , T ) \vert}^{2} dt$$

In general, there are many methods to solve optimization problems, ranging from quasi-Newton methods to genetic algorithms and simulated annealing, to name some. However, not all methods can be applied in practice because of the following reasons: (a) computing the error signal for a given set of parameters may be expensive and very time consuming, (b) the function may be noisy, i.e., computing the function with the same input variables may lead to different values, and (c) the dimension of the problem may be high, depending on the number of parameters being optimized and many optimization methods do not scale well in high dimensions (i.e., “the curse of dimensionality”).

In some embodiments, Bayesian optimization (BO) and/or Reinforcement learning (RL) may be applied to solve the optimization problem. While both methods optimize a target function, Bayesian optimization is more suitable for a black-box/offline optimization, and RL is more suitable for online optimization involving sequential decision making and auxiliary observations, which is suitable for online tracking of environmental parameter change.

The BO method optimizes the parameters for different environmental parameters (or changes or rate of changes) in advance (e.g., by building a lookup table for the parameters for each possible environmental parameter metric), and changing the parameters used in the filter 44 according to the lookup table. BO is trained offline by trying different environmental parameter metrics (e.g., vibration or rate of change of temperature etc.), and changing the filter parameter(s) 46 and observing the resulting clock error. The cost function may be used to find the best parameter(s) 46 that provides a minimal cost function.

RL may be used to explore different parameters 46 and perform other observations such as observation of the metrics of the environmental parameter(s) and previous actions in order to find the best policy (e.g., best filter parameter(s) 46). The RL may then exploit with the best policy, e.g., the best parameters 46. Once the best policy is found exploration may stop. Alternatively, some exploration may continue to be performed even after the best policy is found. If the error signal 34 increases above a given limit and/or a change in environmental parameter(s)) above a given limit is detected, exploration may be restarted or increased to search for a new policy (e.g., different best filter parameter(s) 46). An RL based solution may also be trained offline (to give prior knowledge) to learn a reasonable policy and when encountering a new situation, the RL may explore the actions (e.g., changing the filter parameter(s) 46) to update the policy. A reward is given for minimizing the error function (e.g., the error signal 34). A possible algorithm may be an algorithm from the Actor-Critic family, which is applicable to continuous observations and continuous actions. In some embodiments, because RL algorithms combine online exploration by nature, exploration may be limited to situations where a large error signal is detected, and in that case a warning may be provided to a user until the device 12 returns to its typical error levels.

Various features of the invention which are, for clarity, described in the contexts of separate embodiments may also be provided in combination in a single embodiment. Conversely, various features of the invention which are, for brevity, described in the context of a single embodiment may also be provided separately or in any suitable sub-combination.

The embodiments described above are cited by way of example, and the present invention is not limited by what has been particularly shown and described hereinabove. Rather the scope of the invention includes both combinations and sub-combinations of the various features described hereinabove, as well as variations and modifications thereof which would occur to persons skilled in the art upon reading the foregoing description and which are not disclosed in the prior art.

What is claimed is:

1. A device, comprising:
clock circuitry including:
an oscillator to generate a local clock signal having a clock frequency; and
a hardware clock to maintain a local clock responsively to the local clock signal;
at least one sensor to measure at least one value of at least one environmental parameter;
processing circuitry to find at least one value of at least one filter parameter based on the at least one value of the at least one environmental parameter; and
a filter to:
receive an error signal between a remote clock and the local clock; and
filter the error signal and generate an adjustment to cause the clock circuitry to adjust the local clock signal or the local clock based on the at least one value of the at least one filter parameter.

2. The device according to claim 1, further comprising clock synchronization circuitry to find the error signal between the remote clock and the local clock.

3. The device according to claim 1, further comprising a temperature sensor to measure temperature of the oscillator, the processing circuitry being to find the at least one value of the at least one filter parameter based on the temperature.

4. The device according to claim 3, wherein the processing circuitry is to find the at least one value of the at least one filter parameter based on a change in the temperature.

5. The device according to claim 3, wherein the processing circuitry is to find the at least one value of the at least one filter parameter based on a rate of change of the temperature.

6. The device according to claim 3, wherein the processing circuitry is to find the at least one value of at least one filter parameter based on the temperature and at least one property of the oscillator.

7. The device according to claim 6, wherein the at least one property of the oscillator includes frequency stability as a function of the temperature.

8. The device according to claim 1, further comprising a vibration sensor to measure vibration of the oscillator, the processing circuitry being to find the at least one value of the at least one filter parameter based on the vibration.

9. The device according to claim 8, wherein the processing circuitry is to find the at least one value of the at least one filter parameter based on the vibration and at least one property of the oscillator.

10. The device according to claim 9, wherein the at least one property of the oscillator includes frequency stability as a function of the vibration.

11. The device according to claim 1, wherein the processing circuitry is to:
intermittently sample the at least one environmental parameter over time yielding multiple sampled values of the at least one environmental parameter; and
find updated values of the at least one filter parameter based on the multiple sampled values.

12. The device according to claim 1, wherein the processing circuitry is to:
find a cutoff frequency and an update rate of the filter based on the at least one value of the at least one environmental parameter; and
compute the at least one value of the at least one filter parameter based on the cutoff frequency and the update rate of the filter.

13. The device according to claim 12, wherein the processing circuitry is to perform a table lookup using the at least one value of the at least one environmental parameter to find the cutoff frequency and the update rate.

14. The device according to claim 12, wherein the processing circuitry is to predict the cutoff frequency and the update rate from the at least one value of the at least one environmental parameter using a machine learning model while minimizing clock error.

15. The device according to claim 12, wherein the processing circuitry is to predict the cutoff frequency and the update rate from the at least one value of the at least one environmental parameter using reinforcement learning while minimizing clock error.

16. The device according to claim 12, wherein the processing circuitry is to predict the cutoff frequency and the update rate from the at least one value of the at least one environmental parameter using a Bayesian optimization framework while minimizing clock error.

17. The device according to claim 1, wherein the processing circuitry is to perform a table lookup using the at least one value of the at least one environmental parameter to find the at least one value of the at least one filter parameter.

18. The device according to claim 1, wherein the processing circuitry is to predict the at least one value of the at least one filter parameter from the at least one value of the at least one environmental parameter using a machine learning model while minimizing clock error.

19. The device according to claim 1, wherein the processing circuitry is to predict the at least one value of the at least one filter parameter from the at least one value of the at least one environmental parameter using reinforcement learning while minimizing clock error.

20. The device according to claim 1, wherein the processing circuitry is to predict the at least one value of the at least one filter parameter from the at least one value of the at least one environmental parameter using a Bayesian optimization framework while minimizing clock error.

21. The device according to claim 1, wherein the filter is a PI servo filter and the at least one filter parameter includes PI constants defining a bandwidth of the filter.

22. A method, comprising:
generating a local clock signal having a clock frequency;
maintaining a local clock responsively to the local clock signal;
measuring at least one value of at least one environmental parameter;
finding at least one value of at least one filter parameter based on the at least one value of the at least one environmental parameter;
receiving an error signal between a remote clock and the local clock; and
filtering the error signal and generate an adjustment to cause adjustment of the local clock signal or the local clock based on the at least one value of the at least one filter parameter.
